(19) United States
(12) Patent Application Publication
(10) Pub. No.: US 2010/0044860 A1
(43) Pub. Date: Feb. 25, 2010

(54) Microelectronic substrate or element having conductive pads and metal posts joined thereto using bond layer

(75) Inventors: Belgacem Haba, Saratoga, CA (US); Chang Myung Ryu, Cupertino, CA (US); Kimitaka Endo, Yokohama (JP); Christopher Paul Wade, Los Gatos, CA (US)

Correspondence Address: TESSERA;LERNER DAVID et al., 600 SOUTH AVENUE WEST, WESTFIELD, NJ, 07090, US

(73) Assignee: Tessera Interconnect Materials, Inc., San Jose, CA (US)

(21) Appl. No.: 12/462,208

(22) Filed: Jul. 30, 2009

Related U.S. Application Data
(60) Provisional application No. 61/189,618, filed on Aug. 21, 2008.

(51) Int. Cl. H01L 23/498; H01L 21/768

(52) U.S. Cl. 257/737; 438/614; 257/E23.068; 257/E21.589

(57) ABSTRACT

An interconnection element can include a substrate, e.g., a connection substrate, element of a package, circuit panel or microelectronic substrate, e.g., semiconductor chip, the substrate having a plurality of metal conductive elements such as conductive pads, contacts, bond pads, traces, or the like exposed at the surface. A plurality of solid metal posts may overlie and project away from respective ones of the conductive elements. An intermetallic layer can be disposed between the posts and the conductive elements, such layer providing electrically conductive interconnection between the posts and the conductive elements. Bases of the posts adjacent to the intermetallic layer can be aligned with the intermetallic layer.

### CROSS-REFERENCE TO RELATED APPLICATION

This application claims the benefit of the filing date of U.S. Provisional Application 61/189,618 filed Aug. 21, 2008, the disclosure of which is incorporated by reference herein.

### FIELD OF THE INVENTION

The subject matter of the present application relates to the structure and fabrication of a substrate having metal posts thereon, such as for interconnection with a microelectronic element, e.g., a semiconductor chip and relates to the structure and fabrication of a microelectronic element having posts thereon for interconnection with a substrate.

### BACKGROUND OF THE INVENTION

It is becoming more difficult to package semiconductor chips in a flip-chip manner in which the contacts of the chip face toward corresponding contacts of a package substrate. Increased density of the chip contacts is causing the pitch between contacts to be reduced. Consequently, the volume of solder available for joining each chip contact to the corresponding package contact is reduced. Moreover, smaller solder joints cause the stand-off height between the contact-bearing chip surface and the adjacent face of the package substrate to be reduced. However, when the contact density is very high, the stand-off height may need to be greater than the height of a simple solder joint in order to form a proper underfill between the adjacent surfaces of the chip and package substrate. In addition, it may be necessary to require a minimum stand-off height in order to allow the contacts of the package substrate to move somewhat relative to the contacts of the chip in order to compensate for differential thermal expansion between the chip and the substrate.

One approach that has been proposed to address these concerns involves forming metal columns by electroplating a metal such as copper directly on the chip contacts, using a photoresist mask overlying the chip front surface to define the locations and height of the columns. The chip with the columns extending from the bond pads thereon can then be joined to corresponding contacts of the package substrate. Alternatively, a similar approach can be taken to form metal columns on exposed pads of the substrate. The substrate with the columns extending from the contacts thereon can then be joined to corresponding contacts of the chip.

However, the process of forming the columns by electroplating can be problematic when performed simultaneously over a large area, such as, for example, the entire area of a wafer (having a diameter from about 200 millimeters to about 300 millimeters) or over the entire area of a substrate panel (typically having dimensions of about 500 millimeters square). It is difficult to achieve metal columns with uniform height, size and shape. All of these are very difficult to achieve when the size and height of the columns is very small, e.g., at column diameters of about 75 microns or less and column heights of about 50 microns or less. Variations in the thickness of the photoresist mask and the size of shape of patterns over a large area such as a wafer or substrate panel can interfere with obtaining columns of uniform height, size and shape.

In another method, bumps of solder paste or other metal-filled paste can be stenciled onto conductive pads on an exposed surface of a substrate panel. The bumps can then be flattened by subsequent coining to improve planarity. However, tight process control can be required to form bumps having uniform solder volume, especially when the pitch is very small, e.g., about 200 microns or less. It can also be very difficult to eliminate the possibility of solder-bridging between bumps when the pitch is very small, e.g., about 200 microns or less.

### SUMMARY

In accordance with an embodiment disclosed herein, an interconnection element can include a substrate, e.g., a connection substrate, element of a package, circuit panel or microelectronic substrate which can include a semiconductor chip. In one embodiment, the substrate can include a dielectric element and the conductive elements can be exposed at a surface of the dielectric element. In one embodiment, the substrate can be a semiconductor chip and the conductive elements can include contacts or bond pads of the chip.

The substrate can have a surface and a plurality of metal conductive elements such as conductive pads, contacts, bond pads, traces, or the like exposed at the surface. A plurality of solid metal posts may overlie and project away from respective ones of the conductive elements. An intermetallic layer can be disposed between the posts and the conductive elements, such layer which can provide electrically conductive interconnection between the posts and the conductive elements. Bases of the posts adjacent to the intermetallic layer can be aligned with the intermetallic layer.

In one embodiment, the intermetallic layer can have a higher melting temperature than a melting temperature of an originally provided bond layer used to form the intermetallic layer. In a particular embodiment, the intermetallic layer can include at least one metal that is selected from a tin metal group consisting of tin, tin-copper, tin-lead, tin-zinc, tin-bismuth, tin-indium, tin-silver-copper, tin-zinc-bismuth, and tin-silver-indium-bismuth. In another embodiment, the intermetallic layer can include a metal such as indium, silver or both.

In a particular embodiment, the at least one post can have a base, a tip remote from the base, the tip being disposed at a height from the base, and a waist between the base and the tip. The tip may have a first diameter and the waist may have a second diameter. In a particular embodiment, due to an etching process used to form the post, there can be a difference between the first and second diameters which is greater than 25% of the height of the post.

The posts may extend in a vertical direction above the intermetallic layer and have edges which are curved continuously with respect to the vertical direction from tips of the posts to bases of the posts.

In one embodiment, the posts can extend in a vertical direction above the intermetallic layer and at least one post can include a first etched portion having a first edge, the first edge having a first radius of curvature, and at least one second etched portion between the first etched portion and the intermetallic layer. The second etched portion may have a second edge which has a second radius of curvature, the second radius of curvature being different from the first radius of curvature.

In accordance with an embodiment, a method is provided for fabricating a microelectronic interconnection element which can include joining a sheet-like conductive element to exposed conductive elements of a substrate using a conductive bond layer which may fuse with the sheet-like element and the conductive elements. The substrate may have at least one wiring layer thereon. The sheet-like element can then be patterned to form a plurality of conductive posts projecting in a first direction from the conductive elements. The sheet-like element can be patterned by etching selectively with respect to the bond layer until portions of the bond layer are exposed, and then removing the exposed portions of the bond layer. In a particular embodiment, the bond layer may include tin or indium.

In a particular embodiment, the sheet-like element can include a foil that includes a first metal, an etch barrier layer overlying a surface of the foil and the conductive bond layer overlying a surface of the etch barrier layer remote from the first metal. The sheet-like element can be joined with the conductive elements by processing including joining the bond layer to the conductive elements. In one embodiment, the foil can then be etched selectively with respect to the etch barrier layer until portions of the etch barrier layer are exposed. Exposed portions of the etch barrier layer and portions of the bond layer can then be removed between the conductive posts.

In one variation, the sheet-like element can include a foil including a first metal and a conductive bond layer overlying a surface of the foil, and can be joined with the conductive elements by processing including joining the bond layer with the conductive elements. The sheet-like element can be patterned by etching the foil selectively with respect to the bond layer until portions of the bond layer are exposed, after which exposed portions of the bond layer can be removed.

In a particular embodiment, the method may further include joining the first bond layer with a second bond layer previously provided on the conductive elements. The materials of the first and second bond layers can be the same or different. In a particular embodiment, one of the first and second bond layers can include tin and gold and the other of the first and second bond layers can include silver and indium.

In a particular embodiment, the foil may consist essentially of a first metal and the etch barrier layer may consist essentially of an etch barrier layer which is not attacked by the etchant. For example, in one embodiment, the first metal may include copper and the etch barrier layer may consist essentially of nickel.

In a method in accordance with an embodiment herein, a microelectronic interconnection element can be fabricated. In such method, a sheet-like conductive element can be joined with exposed conductive pads of a substrate, e.g., microelectronic substrate or a dielectric element having at least one wiring layer thereon. The sheet-like conductive element can then be patterned to form a plurality of conductive posts projecting in a first direction from the conductive pads. The sheet-like conductive element can include a foil including a first metal and a second metal layer overlying a surface of the foil. In such method, the second metal layer can be joined to the conductive pads with a bond material and the foil may be etched selectively with respect to the second metal layer until portions of the second metal layer are exposed. The exposed portions of the second metal layer may then be subsequently removed.

In accordance with one embodiment, a method of fabricating a microelectronic interconnection element is provided. In such method, first ends of metal posts which are at least partially disposed within openings in a mandrel are juxtaposed with conductive elements of a substrate, with a conductive bond layer disposed between the first ends of the posts and the conductive elements. Such bond layer can then be heated to form electrically conductive joints between the first ends of the posts and the conductive elements. The mandrel can then be removed to expose the posts such that posts project away from the conductive elements.

In one embodiment, prior to joining the posts with the conductive elements, a plurality of the conductive posts can be formed within the openings of the mandrel by processing including plating a layer of metal within the openings.

In a particular embodiment, the mandrel may include a first metal layer exposed at interior walls of the openings, and the conductive posts may include a second metal layer overlying the first metal layer within the openings. An etch barrier layer can be disposed between the first and second metal layers. In such case, processing to remove the mandrel can include removing the first metal layer selectively with respect to the etch barrier metal layer.

In a particular embodiment, each of the first and second metal layers can include copper. In one embodiment, the etch barrier metal layer can consist essentially of nickel, such that the copper layer can be etched selectively with respect to the nickel layer.

A microelectronic interconnection element in accordance with one embodiment of the invention can include a substrate having a major surface extending in a first direction and a second direction transverse to the first direction. A plurality of conductive elements can be exposed at the major surface. Solid metal posts can overlie the conductive elements and project in a third direction away from respective ones of the conductive elements. A conductive bond layer can have a first face joined to the respective ones of the conductive elements.

A method is provided in accordance with an embodiment herein which can include juxtaposing a metal foil extending in first and second directions with a plurality of electrically conductive elements of a substrate and an electrically conductive bond layer disposed between a face of the metal foil and the conductive elements. Heat can then be applied to join the metal foil with the conductive elements and form an intermetallic layer at least at junctions between the metal foil and the conductive elements. The metal foil can then be patterned to form a plurality of solid metal posts extending away from the conductive elements and away from a surface of the substrate.

In one embodiment, the intermetallic layer can have a melting temperature higher than a temperature at which a joining process usable to form electrically conductive interconnections between the posts and contacts of an external component.

In a particular embodiment, the substrate can include a microelectronic element such as a semiconductor chip or including a semiconductor chip and the conductive elements can include pads at a face of the semiconductor chip.

### BRIEF DESCRIPTION OF THE DRAWINGS

FIG. 1 is a fragmentary sectional view illustrating a stage in a method of fabricating a substrate having protruding conductive posts in accordance with one embodiment.

FIG. 1A is a partial fragmentary sectional view further illustrating interconnection between a metal foil and a conductive pad of a substrate.

FIG. 1B is a partial fragmentary sectional view further illustrating a stage in formation of an interconnection element in accordance with one embodiment.

FIG. 2 is a plan view corresponding to FIG. 1 of a partially fabricated substrate depicted in FIG. 1, the section taken through line 1-1 of FIG. 2.

FIG. 3 is a plan view corresponding to FIG. 1 of a layered metal structure depicted in FIG. 1.

FIG. 4 is a fragmentary sectional view illustrating a stage in a method of fabricating a substrate subsequent to the stage illustrated in FIGS. 1-3.

FIG. 4A is a partial fragmentary sectional view further illustrating structure of a conductive post formed in accordance with an embodiment.

FIG. 4B is a partial fragmentary sectional view illustrating structure of a conductive post formed in accordance with a variation of such embodiment.

FIG. 4C is a partial fragmentary sectional view further illustrating a stage in formation of an interconnection element in accordance with a variation of an embodiment.

FIGS. 4D, 4E, 4F and 4G are sectional views illustrating stages in formation of an interconnection element in accordance with a variation of an embodiment.

FIG. 5 is a fragmentary sectional view illustrating a stage in a method of fabricating a substrate subsequent to the stage illustrated in FIG. 4.

FIG. 6 is a fragmentary sectional view illustrating a completed substrate having protruding conductive posts in accordance with one embodiment.

FIG. 6A is a fragmentary sectional view illustrating a microelectronic assembly including an interconnection element and a microelectronic element connection therewith and other structure.

FIG. 7 is a fragmentary sectional view illustrating a completed substrate having protruding conductive posts in accordance with a variation of the embodiment illustrated in FIG. 6.

FIG. 8 is a fragmentary sectional view illustrating a completed substrate having protruding conductive posts in accordance with a variation of the embodiment illustrated in FIG. 7.

FIGS. 9-10 are fragmentary sectional views illustrating stages in a method of fabricating a substrate having protruding conductive posts in accordance with a variation of the embodiment illustrated in FIGS. 1-6.

FIG. 11 is a fragmentary sectional view illustrating a stage in a method of fabricating a substrate having protruding conductive posts in accordance with a variation of the embodiment illustrated in FIGS. 1-6; the section taken through line 11-11 of FIG. 12.

FIG. 12 is a plan view corresponding to FIG. 11.

FIGS. 13, 14, 15 and 16 are fragmentary sectional views illustrating stages subsequent to the stage shown in FIGS. 11-12 in a method of fabricating a substrate having protruding conductive posts in accordance with a variation of the embodiment illustrated in FIGS. 1-6.

FIGS. 17, 18 and 19 are fragmentary sectional views illustrating stages in a method of fabricating a substrate having protruding conductive posts in accordance with a variation of the embodiment illustrated in FIGS. 11-16.

FIG. 20 is a fragmentary sectional view illustrating a layered metal structure for use in a method of fabrication in accordance with a variation of the embodiment illustrated in FIGS. 11-19.

FIG. 21 is a plan view illustrating a method of fabrication in accordance with a variation of an embodiment such as illustrated in one or more of the foregoing described embodiments.

### DETAILED DESCRIPTION

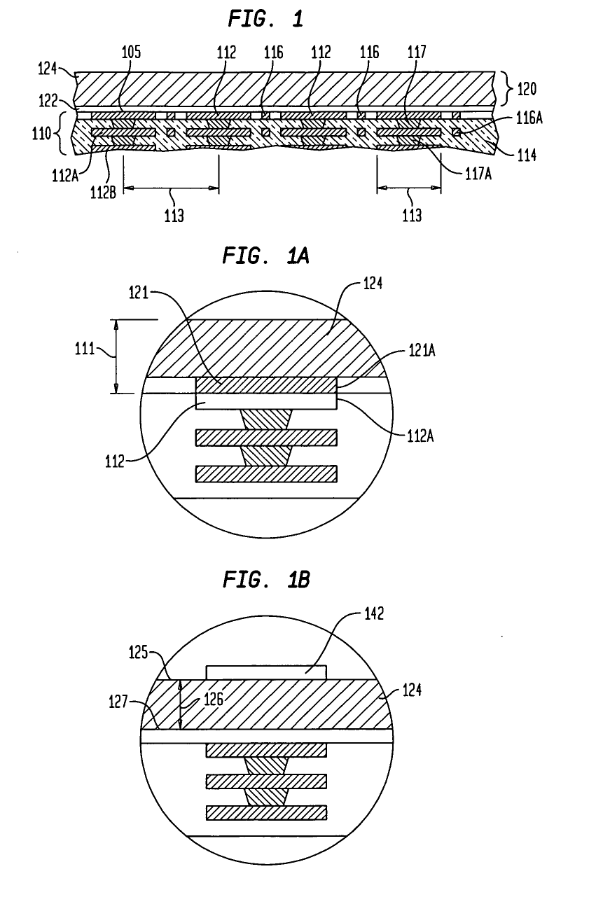

FIG. 1 is a fragmentary sectional view illustrating a stage in a method of fabricating a substrate having a copper bump interface in accordance with one embodiment herein. As seen in FIG. 1, an interconnection substrate 110, which can be fully or partially formed, is joined with a layered metal structure 120 such that a bond layer 122 of the layered metal structure contacts conductive pads 112 exposed at a major surface of a dielectric element 114. In one particular embodiment, the substrate can include a dielectric element bearing a plurality of conductive elements which can include contact, traces or both contacts and trace. The contacts can be provided as conductive pads having larger diameters than widths of the traces. Alternatively, the conductive pads can be integral with the traces and can be of approximately the same diameter or only somewhat larger than widths of the traces. Without limitation, one particular example of a substrate can be a sheet-like flexible dielectric element, typically made of a polymer, e.g., polyimide, among others, having metal traces and contacts patterned thereon, the contacts being exposed at least one face of the dielectric element. As used in this disclosure, a statement that an electrically conductive structure is “exposed at” a surface of a dielectric structure indicates that the electrically conductive structure is available for contact with a theoretical point moving in a direction perpendicular to the surface of the dielectric structure toward the surface of the dielectric structure from outside the dielectric structure. Thus, a terminal or other conductive structure which is exposed at a surface of a dielectric structure may project from such surface; may be flush with such surface; or may be recessed relative to such surface and exposed through a hole or depression in the dielectric.

In one embodiment, the dielectric element may have a thickness of 200 micrometers or less. In a particular example, the conductive pads can be very small and can be disposed at a fine pitch. For example, the conductive pads may have dimensions 113 in a lateral direction of 75 microns or less and can be disposed at a pitch of 200 microns or less. In another example, the conductive pads may have dimensions in a lateral direction of 50 microns or less and can be disposed at a pitch of 150 microns or less. In another example, the conductive pads may have dimensions in a lateral direction of 35 microns or less and can be disposed at a pitch of 100 microns or less. These examples are illustrative; conductive pads and their pitch can be larger or smaller than those indicated in the examples. As further seen in FIG. 1, conductive traces 116 may be disposed at the major surface of the dielectric element 114.

For ease of reference, directions are stated in this disclosure with reference to a “top” surface 105 of a substrate 114, i.e., the surface at which pads 112 are exposed. Generally, directions referred to as “upward” or “rising from” shall refer to the direction orthogonal and away from the top surface 128. Directions referred to as “downward” shall refer to the directions orthogonal to the chip top surface 128 and opposite the upward direction. A “vertical” direction shall refer to a direction orthogonal to the chip top surface. The term “above” a reference point shall refer to a point upward of the reference point, and the term “below” a reference point shall refer to a point downward of the reference point. The “top” of any individual element shall refer to the point or points of that element which extend furthest in the upward direction, and the term “bottom” of any element shall refer to the point or points of that element which extend furthest in the downward direction.

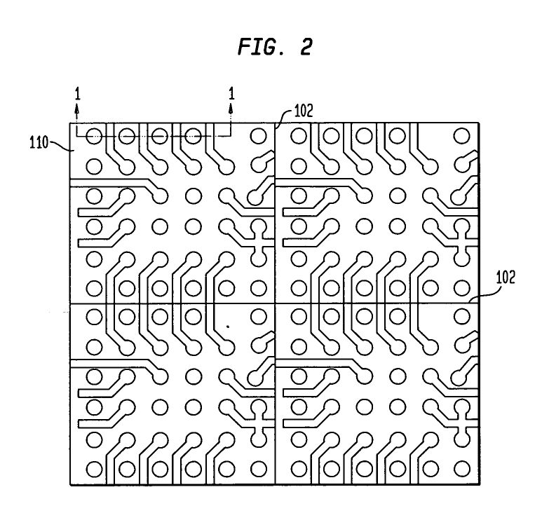

The interconnection substrate can further include one or more additional conductive layers within the dielectric element 114 which have additional conductive pads 112A, 112B and vias 117, 117A for interconnection between the pads 112, 112A, 112B of different layers. The additional conductive layers can include additional traces 116A. As best seen in FIG. 2, the interconnection substrate 110 (shown in panel form) has conductive pads 112 and conductive traces 116 exposed at the top surface 105 of a dielectric element.

As illustrated in FIG. 2, the traces 116 can be disposed between the conductive pads 112 or can be disposed in other locations. The particular pad and trace pattern is merely illustrative of many possible alternative configurations. As illustrated in FIG. 2, some or all of the traces can be directly connected to conductive pads 112 at the major surface. Alternatively, some or all of the conductive traces 116 may not have any connections with the conductive pads 112. As depicted in FIG. 2, the interconnection substrate can be one of a many such interconnection substrates attached at peripheral edges 102 of the substrates within a larger unit such as a panel or strip during processing. In one embodiment, the dimensions of the panel can be 500 millimeters square, i.e., the panel can have a dimension of 500 millimeters along an edge of the panel in a first direction and have a dimension of 500 millimeters along another edge of the panel in a second direction transverse to the first direction. In one example, when completed, such panel or strip may be divided into a number of individual interconnection substrates. The so-formed interconnection substrates may be suitable for flip-chip interconnection with a microelectronic element such as a semiconductor chip.

The layered metal structure 120 includes a patternable metal layer 124 and a bond layer 122. The patternable metal layer 124 can include a foil consisting essentially of a metal such as copper. The foil typically has a thickness less than 100 microns. In a particular example, the thickness of the foil can be a few tens of microns. In another example, the thickness of the foil can be more than 100 microns. The bond layer typically includes a bonding material suitable for bonding the exposed conductive pads 112 to the metal included in the foil 124.

In particular examples, the bond layer consists essentially of tin, or alternatively of indium, or a combination of tin and indium. Various bond layer materials as well as interconnection element structures and fabrication methods are described in commonly owned U.S. application Ser. No. 12/317,707 filed Dec. 23, 2008, the disclosure of which is incorporated by reference herein. In one embodiment, the bond layer can include one or more metals which has a low melting point (“LMP”) or low melting temperature which is sufficiently low to make it possible to form an electrically conductive connection by melting and fusing to metal elements with which it contacts.

For example, an LMP metal layer generally refers to any metal having a low melting point which allows it to melt at sufficiently low temperatures that are acceptable in view of the property of an object to be joined. Although the term “LMP metal” is sometimes used to generally refer to metals having a melting point (solidifying point) that is lower than the melting point of tin (about 232° C.=505 K), the LMP metal of the present embodiment is not always restricted to metals having a melting point lower than that of tin, but includes any simple metals and metal alloys that can appropriately bind to the material of the bump appropriately and that have a melting point temperature that parts for which an interconnection element is used for connection can tolerate. For example, for an interconnection element provided on a substrate using a dielectric element which has low heat resistance the melting point of the metal or metal alloy used according to the presently disclosed embodiments should be lower than the allowable temperature limit of the dielectric element 114. (FIG. 1).

In one embodiment, the bond layer 122 can be a tin metal layer such as tin or an alloy of tin, such as tin-copper, tin-lead, tin-zinc, tin-bismuth, tin-indium, tin-silver-copper, tin-zinc-bismuth and tin-silver-indium-bismuth, for example. These metals have a low melting point and an excellent connectivity with respect to a metal foil made of copper and posts which can be formed therefrom by etching the metal foil. Furthermore, if the conductive pad 112 includes or consists of copper, the tin metal layer 122 has excellent connectivity with respect to the pad 112. The composition of such tin metal layer 122 does not always need to be uniform. For example, the tin metal layer may be a single layer or multilayered. Furthermore, by sufficiently heating the substrate with the tin metal layer and metal foil thereon to a sufficient temperature such as above the melting point of the tin metal layer, the tin metal layer can melt and fuse the metal foil with the conductive pads.

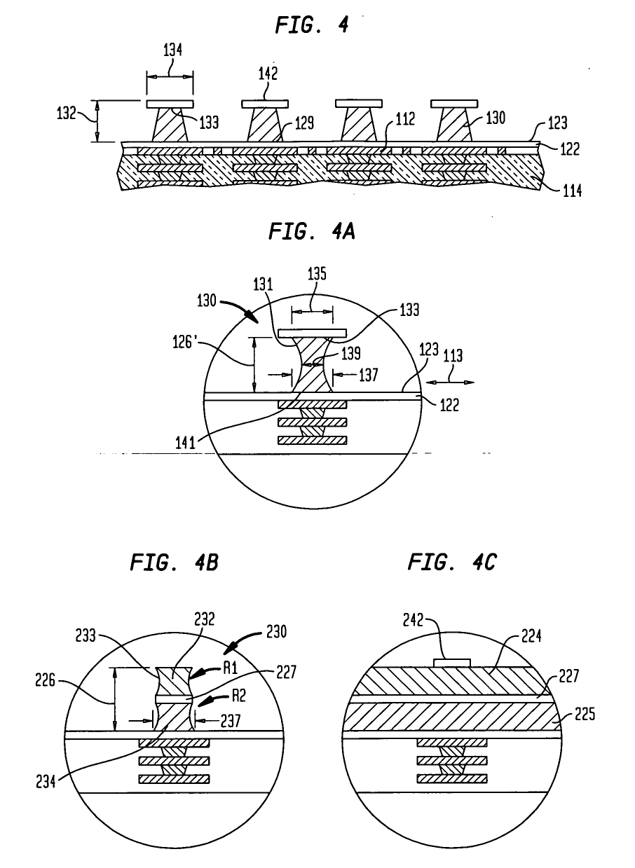

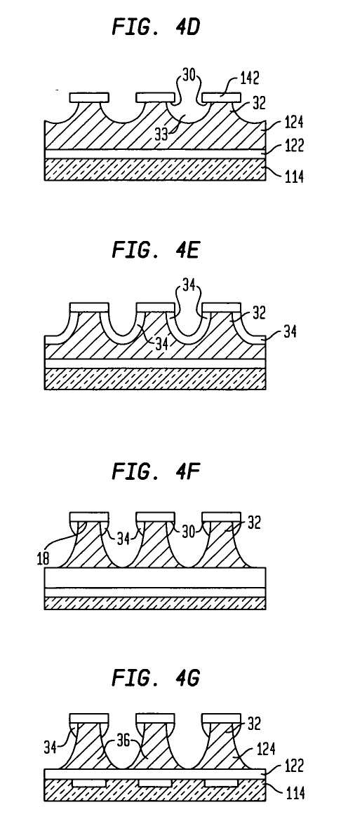

During such process, material from the tin metal layer can diffuse outwardly into the pads 112 or the metal foil or both. Conversely, material from the pads 112, the metal foil or both can diffuse therefrom into the tin metal layer. In such manner, the resulting structure can include an “intermetallic” layer 121 that joins the metal foil with the conductive pads, such intermetallic layer which can include a solid solution of a material from the tin metal layer with the material of the foil 124, the pad 112 or both. Because of diffusion between the tin metal layer and the conductive pads, the resulting intermetallic layer can be aligned with portions of the conductive pads contacted by the tin metal layer. In one embodiment, as seen in FIG. 1A, an edge 121A of the intermetallic layer 121 can be at least roughly aligned in a vertical direction 111 with an edge 112A of the conductive pad 112. Within the intermetallic layer, the composition ratio of the intermetallic layer may change gradually at one or both of an interface thereof with the pad 112 or an interface with the foil 124 or post 130 (FIG. 4) which is subsequently patterned therefrom. Alternatively, the compositions of the tin metal layer, pad 112 and post 130 can undergo metallurgical segregation or aggregation at their interfaces or between the interfaces, such that the composition of one or more of the conductive pad, post or tin metal layer, if any tin metal layer remains, can change with the depth from the interface between such elements. This can occur even though the tin metal layer 122, pad 112 or metal foil 124 can have a single composition when it is created.

The intermetallic layer can have such composition that the layer can have a melting temperature which is higher than a temperature at which a joining process can be performed to join the posts 130 of the interconnection element with contacts of an external component, e.g., another substrate, microelectronic element, passive device, or active device. In such way, the joining process can be performed without causing the intermetallic layer to melt, thus maintaining positional stability of the posts relative to conductive elements, e.g., pads or traces of the substrate from which the posts project in a direction away from the surface of the substrate.

In one embodiment, the intermetallic layer can have a melting temperature below a melting temperature of a metal, e.g., copper, of which the pads 112 essentially consist. Alternatively or in addition thereto, in one embodiment, the intermetallic layer can have a melting temperature below a melting temperature of a metal, e.g., copper, of which the foil 124 and the posts 130 are subsequently formed therefrom.

In one embodiment, the intermetallic layer can have a melting temperature which is higher than a melting temperature of the bond layer as originally provided, that is, a melting temperature of the bond layer as it exists before the substrate with the bond layer and metal foil thereon are heated to form the intermetallic layer.

The bond layer need not be a tin metal layer. For example, the bond layer can include a joining metal such as indium or an alloy thereof. The above description regarding the formation and composition of an intermetallic layer can also apply when using such other type of bond layer such that materials can diffuse between such bond layer and one or more of the foil and the conductive pads to form the intermetallic layer.

The bond layer can have a thickness ranging from about one micron or a few microns and greater. A relatively thin diffusion barrier layer (not shown) can be provided between the bond layer and the foil. In one example, the diffusion barrier layer can include a metal such as nickel. The diffusion barrier layer can help avoid diffusion of the bond metal into the foil, such as, for example, when the foil consists essentially of copper and the bond layer consists essentially of tin or indium. In another example, the bond layer can include a conductive paste such as a solder paste or other metal-filled paste or paste containing a conductive compound of a metal or combination thereof. For example, a uniform layer of solder paste can be spread over the surface of the foil. Particular types of solder paste can be used to join metal layers at relatively low temperatures. For example, indium- or silver-based solder pastes which include “nanoparticles” of metal, i.e., particles having long dimensions typically smaller than about 100 nanometers, can have sintering temperatures of about 150° C. The actual dimensions of the nanoparticles can be significantly smaller, e.g., having dimensions from about one nanometer and larger. In another example, the bond layer can include a conductive adhesive. In yet another example, the bond layer can include an anisotropic conductive adhesive film which includes metal particles dispersed within an insulating polymeric film.

In a particular embodiment, more than one bond layer may be used to join the metal foil with the conductive pads of the substrate. For example, a first bond layer can be provided on the foil and a second bond layer can be provided on the conductive pads of the substrate. Then, the foil having the first bond layer thereon can be juxtaposed with the conductive elements having the second bond layer thereon and heat can be applied to the first and second bond layers to form electrically conductive joints between the conductive pads and the foil. The first and second bond layers can have the same or different compositions. In one embodiment, one of the first and second bond layers can include tin and gold and the other of the first and second bond layers can include silver and indium.

In yet another example, the bond layer can include a “reactive foil”, which typically has a structure of dissimilar metals which react exothermically upon activation, such as when pressure is applied. For example, a commercially available reactive foil can include a series of alternating layers of nickel and aluminum. When activated by pressure, the reactive foil reaches locally high internal temperatures sufficient to bond metals with which it is in contact.

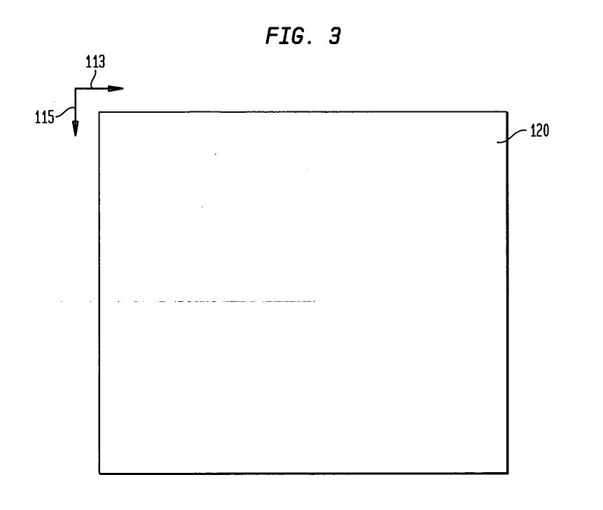

As best seen in FIG. 3, the foil can be continuous in lateral directions 113, 115 over at least the dimensions of the partially formed interconnection substrate, the foil being covered with a bond layer which is continuous over the same dimensions. In one example, the layered metal structure can be of the same dimensions as a substrate panel, e.g., 500 millimeters square.

As depicted in FIG. 1, the bond layer 122 is joined to the conductive pads 112 of the partially fabricated substrate. Then, the metal foil 124 is patterned subtractively by photolithography to form conductive or metal posts. For example, a photoresist or other mask layer can be patterned by photolithography to form an etching mask 142 overlying a top surface 125 of the metal foil, as seen in FIG. 1B. The metal foil 124 can then be selectively etched from the top surface in locations not covered by the etching mask, to form solid metal posts 130 (FIG. 4).

When viewed from above an exposed surface 123 of the bond layer 122, the base 129 of each post can have a circular area in contact with the bond layer which can be larger than the tip (apex) 133 of the post. The tip, which is disposed at a height 132 above the surface 123 of bond layer can have a smaller area than the base. Typically, the tip also has circular area when viewed from above the bond layer surface 123. The shape of the post is rather arbitrary and may be not only a truncated cone (a part of a cone whose top portion is cut off along a face parallel to its bottom face) shown in the drawings, but also of a cylinder or a cone or any other similar shape known in the art, such as a cone with round top or a plateau shape. Furthermore, in addition to or rather than the three dimensional (3D) shape having a circular cross-section, which is called a “solid of revolution”, such as the truncated cone, the post 130 may have an arbitrary shape such as any three dimensional shape having a polygonal horizontal cross-section. Typically, the shape can be adjusted by changing the resist pattern, etching conditions or the thickness of the original layer or metal foil from which the post is formed. Although the dimensions of the post 130 are also arbitrary and are not limited to any particular ranges, often, it may be formed to project from an exposed surface of the substrate 110 by 10 to 500 micrometers, and if the post has the circular cross-section, the diameter may be set in a range of a few tens of microns and greater. In a particular embodiment the diameter of the post can range between 0.1 mm and 10 mm. In a particular embodiment, the material of the post 130 can be copper or copper alloy. The copper alloy can include an alloy of copper with any other metal or metals.

Typically, the posts are formed by etching the metal foil isotropically, with the mask 142 (FIG. 1B) disposed on or above the metal foil such that etching proceeds from the top surface 125 of the metal foil in a direction of a thickness 126 (FIG. 4A) of the metal foil, i.e., towards a bottom surface 127 of the metal foil. Simultaneously, etching proceeds in lateral directions 113, 115 (FIG. 3) in which the top surface of the metal foil extends. Etching can proceed until a surface 123 of the bond layer 122 is fully exposed between posts such that the height 126′ of each post from the exposed surface 123 of the bond layer can be the same as the thickness 126 of the metal foil 124 (FIG. 1B).

Posts 130 formed in such manner can have a shape as seen in FIG. 4A, in which the edge 131 of the post may curve continuously from the tip 133 to the base 141 of the post in contact with the underlying bond layer 122 or intermetallic layer formed therefrom. In one example, the edge 131 of the post may be curved over 50% or more of the height 126′ of the tip 133 above the surface 123 of the bond layer 122 or intermetallic layer in contact with the post. The tip of each post typically has a width 135 in a lateral direction 113 which is smaller than the width 137 of the base of the post. The post may also have a waist having a width 139 which is smaller than each of the widths 135, 137 of the tip 133 and the base 141.

The width 135 of the tip can be the same or different in the lateral directions 113, 115 in which the metal foil extends. When the width is the same in the two directions, the width 135 can represent a diameter of the tip. Likewise, the width 137 of the base can be the same or different in lateral directions 113, 115 of the metal foil, and when it is the same, the width 137 can represent a diameter of the base. Similarly, the width 139 of the waist can be the same or different in lateral directions 113, 115 of the metal foil, and when it is the same, the width 139 can represent a diameter of the waist. In one embodiment, the tip can have a first diameter, and the waist can have a second diameter, wherein a difference between the first and second diameters can be greater than 25% of the height of the post extending between the tip and base of the post.

FIG. 4 illustrates the interconnection element after conductive posts 130 are formed by etching completely through the metal foil 124 to expose the underlying bond layer 122. In a particular example, the conductive posts can have a height from a few tens of microns and lateral dimensions, e.g., diameter from a few tens of microns. In a particular example, the height and diameter can each be less than 100 microns. The diameter of the posts is less than the lateral dimensions of the conductive pads. The height of each post can be less than or greater than the post's diameter.

FIG. 4B illustrates an alternative embodiment in which the post 230 is formed with a base having a width 237 which can be narrower in relation to a height 226 of the post than the width 137 of the base when the post is formed as discussed with reference to FIG. 4A. Thus, a post 230 having a greater height to width aspect ratio may be obtained than the post 130 formed as discussed above. In a particular embodiment, the post 230 can be formed by etching portions of a layered structure (FIG. 4C) using a masking layer 242, where the layered structure including a first metal foil 224, a second metal foil 225 and an etch barrier layer 227 sandwiched between the first metal foil and the second metal foil. The resulting post 230 can have an upper post portion 232 and a lower post portion 234 and can have an etch barrier layer 227 disposed between the upper and lower post portions. In one example, the metal foil consists essentially of copper and the etch barrier 227 consists essentially of a metal such as nickel that is not attacked by an etchant that attacks copper. Alternatively, the etch barrier 227 can consist essentially of a metal or metal alloy that can be etched by the etchant used to pattern the metal foil, except that the etch barrier 227 is etched more slowly than the metal foil. In such manner, the etch barrier protects the second metal foil 225 from attack when the first metal foil is being etched in accordance with masking layer 242 to define an upper post portion 232. Then, portions of the etch barrier 227 exposed beyond an edge 233 of the upper post portion 232 are removed, after which the second metal foil 225 is etched, using the upper post portion as a mask.

The resulting post 230 can include a first etched portion having a first edge, wherein the first edge has a first radius of curvature R1. The post 230 also has at least one second etched portion between the first etched portion and the intermetallic layer, wherein the second etched portion has a second edge having a second radius of curvature R2 that is different from the first radius of curvature.

In one embodiment, the upper post portion 232 may be partially or fully protected from further attack when etching the second metal foil to form the lower post portion. For example, to protect the upper post portion, an etch-resistant material can be applied to an edge or edges 233 of the upper post portion prior to etching the second metal foil. Further description and methods of forming etched metal posts similar to the posts 230 shown in FIG. 4B are described in commonly owned U.S. application Ser. No. 11/717,587 filed Mar. 13, 2007, the disclosure of which is incorporated herein by reference.

In one example, the starting structure need not include an etch barrier layer sandwiched between first and second metal foils. Instead, the upper post portion can be formed by incompletely etching, e.g., “half-etching” a metal foil, such that projecting portions 32 of the metal foil are defined as well as recesses 33 between the projecting portions where the metal foil has been exposed to the etchant. After exposure and development of a photoresist as a masking layer 142, the foil 124 can be etched as shown in FIG. 4D. Once a certain depth of etching is reached, the etching process is interrupted. For example, the etching process can be terminated after a predetermined time. The etching process leaves first post portions 32 projecting upwardly away from the substrate 114. with recesses 33 defined between the first portions. As the etchant attacks the foil 124, it removes material beneath the edges of masking layer 142, allowing the masking layer to project laterally from the top of the first post portions 32, denoted as overhang 30. The first masking layer 142 remains at particular locations as shown.

Once the foil 124 has been etched to a desired depth, a second layer of photoresist 34 (FIG. 4E) is deposited onto an exposed surface of the foil 124. In this instance, the second photoresist 34 can be deposited onto the recesses 33 within the foil 124, i.e., at locations where the foil has been previously etched. Thus, the second photoresist 34 also covers the first post portions 32. In one example, an electrophoretic deposition process can be used to selectively form the second layer of photoresist on the exposed surface of the foil 124. In such case, the second photoresist 34 can be deposited onto the foil without covering the first photoresist masking layer 142.

At the next step, the substrate with the first and second photoresists 142 and 34 is exposed to radiation and then the second photoresist is developed. As shown in FIG. 4F, the first photoresist 142 can project laterally over portions of the foil 124, denoted by overhang 30. This overhang 30 prevents the second photoresist 34 from being exposed to radiation and thus prevents it from being developed and removed, causing portions of the second photoresist 34 to adhere to the first post portions 32. Thus, the first photoresist 142 acts as a mask to the second photoresist 34. The second photoresist 34 is developed by washing so as to remove the radiation exposed second photoresist 34. This leaves the unexposed portions of second photoresist 34 on the first post portions 32.

Once portions of the second photoresist 34 have been exposed and developed, a second etching process is performed, removing additional portions of the foil 124, thereby forming second post portions 36 below the first post portions 32 as shown in FIG. 4G. During this step, the second photoresist 34, still adhered to first post portions 32, protects the first post portions 32 from being etched again.

These steps may be repeated as many times as desired to create the preferred aspect ratio and pitch forming third, fourth or nth post portions. The process may be stopped when the bond layer 122 or intermetallic layer is reached, such layer which can act as an etch-stop or etch-resistance layer. As a final step, the first and second photoresists 142 and 34, respectively, may be stripped entirely.

In such manner, posts having a shape similar to the shape of posts 230 (FIG. 4B) can be formed, but without requiring an internal etch barrier 227 to be provided between upper and lower post portions as seen in FIG. 4B. Using such method, posts having a variety of shapes can be fabricated, in which the upper post portions and lower post portions can have similar diameters, or the diameter of the upper post portion can be larger or smaller than that of a lower post portion. In a particular embodiment, the diameter of the post can become progressively smaller from tip to base or can become progressively larger from tip to base, by successively forming portions of the posts from the tips to the bases thereof using the above-described techniques.

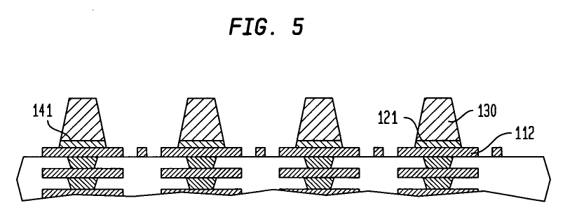

Next, as illustrated in FIG. 5, portions of the bond layer which are exposed between the posts are removed, such as by selective etching, a post-etch cleaning process, or both, such that each post 130 remains firmly bonded to a conductive pad 112 through a remaining portion of the intermetallic layer 121 and a portion of the bond layer, if any, which remains. As a result, the bases 141 of the posts which are adjacent to the intermetallic layer or in contact therewith can be aligned with the intermetallic layer, except for some undercut or overcut of the intermetallic layer which can occur within manufacturing tolerances. Also as a result of the foregoing processing, the traces 116 can become exposed between the posts.

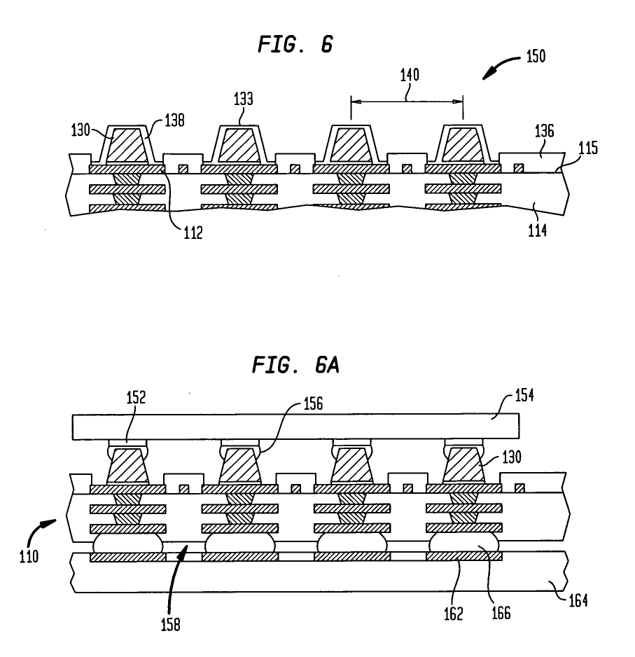

Subsequently, in the stage illustrated in FIG. 6, a solder mask 136 is applied onto an exposed major surface 115 of the dielectric element 114 and patterned. As a result, the conductive posts 130 and the conductive pads 112 can then be exposed within openings of the solder mask 136. A finish metal 138 containing one or more thin layers of metal such as gold or tin and gold can then be applied to exposed surfaces of the posts 130 and the pads 112, to complete the interconnection element. In the interconnection element 150 depicted in FIG. 6, the tips 133 of the conductive posts have a high degree of planarity because they are formed by etching a single metal foil of uniform thickness. Moreover, the pitch 140 obtained between adjacent posts can be very small, e.g., less than 150 microns, and in some cases even smaller, because the dimensions and shape of each post can be controlled well through the etching process. The interconnection element 150 is now in a form usable to form flip-chip interconnections with a corresponding solder bump array of a microelectronic element, such as a semiconductor chip, for example. Alternatively, a mass or coating of solder or joining metal, e.g., tin, indium or a combination of tin and indium can be formed over the finish metal at at least the tips 133, such mass or coating available for forming conductive interconnections with the microelectronic element.

Thus, as shown in FIG. 6A, the posts 130 of the interconnection element 110 can be joined with corresponding contacts 152 of a microelectronic element 160 or semiconductor chip, such as by fusing thereto using a solder 156 or other joining metal.

In yet another alternative, the posts 130 of the interconnection element can be joined to contacts of a semiconductor chip in a solder-less manner, such as by diffusion bonding to corresponding conductive pads or columns exposed at a surface of the semiconductor chip. When the posts 130 of the interconnection element 110 is joined to a semiconductor chip, such as a microelectronic element, e.g., integrated circuit (“IC”), the interconnection element may also be electrically connected to a circuit panel 164 or wiring board. For example, the interconnection element may be connected to such circuit panel 164 at a surface 158 of the interconnection element remote from the posts. In this way, electrically conductive interconnection can be provided between the microelectronic element 154 and the circuit panel 164 through the interconnection element being connected to pads 162 of the circuit panel. If the interconnection element is joined with the microelectronic element 154 and to a circuit panel 164, it the posts may also be connected to another microelectronic element or other circuit panel so that the interconnection element can be used to establish connection between multiple microelectronic elements and at least one circuit panel. In yet another example, the interconnection element may be joined to interface contacts of a testing jig, such that when the posts are pressed into contact with the contacts 152 of the chip without forming permanent interconnections, electrically conductive connection can be established between the testing jig and the microelectronic element through the interconnection element 110.

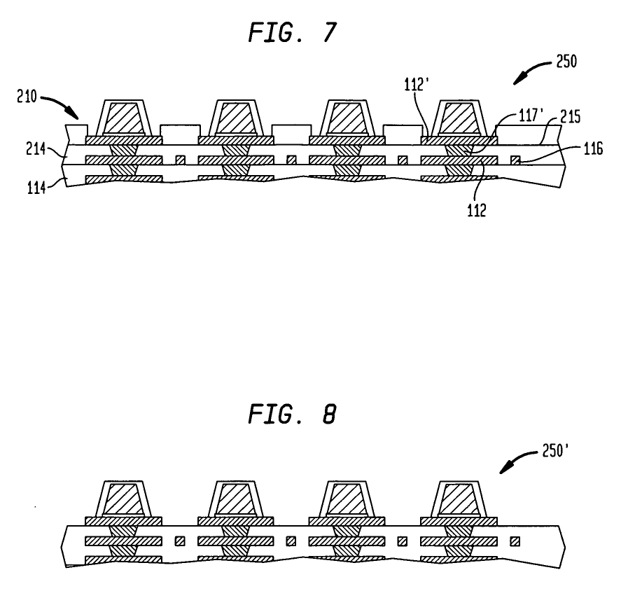

FIG. 7 illustrates an interconnection element 250 in accordance with an alternative embodiment. As shown therein, no traces are exposed at a major surface 215 of the interconnection element. Instead, traces 116 are disposed below the major surface such that they are covered by the material of the dielectric element 210. Interconnection element 250 can be formed starting from the partially fabricated interconnection element 110 (FIG. 1) having conductive pads 112 and traces 116 and depositing a layer 214 of dielectric material thereon. Openings can then be formed in the dielectric layer 214, such as by laser drilling, which can then be electroplated or filled with a conductive paste (e.g., solder paste or silver-filled paste) to form vias 117′. Conductive pads 112′ can then be formed which are exposed at the major surface 215 of the dielectric element 210. Processing then continues as described above (FIGS. 1 through 6). One possible advantage of forming the interconnection element in this way is that traces 116 remain protected by the additional dielectric layer 214 during processing. In addition, the solder mask 136 between the conductive pads may not be necessary.

FIG. 8 depicts an interconnection element 250′ similar to that shown in FIG. 7 but in which the step of forming the solder mask has been eliminated.

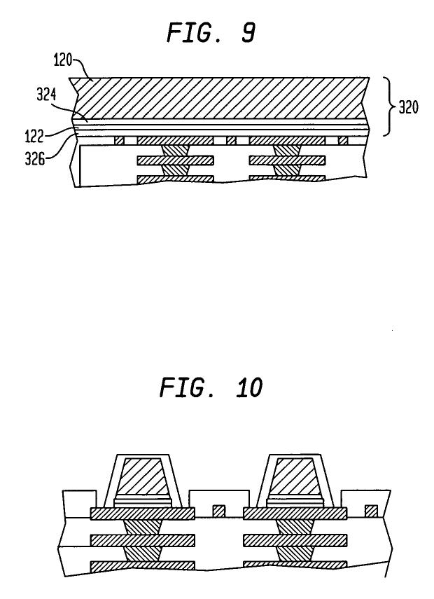

In a particular embodiment of the invention as illustrated in FIG. 9, the layered metal structure 320 includes the metal foil 120 and bond layer 122 as described above (FIGS. 1, 3), but also includes etch barrier layers 324 and 326. The etch barrier layer 324 includes a material which is not attacked by an etchant which is used to pattern the metal foil. The etch barrier layer 326 includes a material which is not attacked by an etchant or other chemical used to remove portions of the bond layer 122. In a particular example, when the metal foil 120 includes copper, the etch barrier layer 324 between the copper foil and the barrier layer can consist essentially of nickel. In this way, the copper foil can be etched with a high degree of selectivity relative to the nickel etch barrier, and thereby protect the bond layer and other structure from erosion when the foil is etched. Thereafter, the etch barrier 324 is removed, such as by etching the etch barrier with an appropriate chemistry, such that portions of the bond layer become exposed between the posts. The exposed portions of the bond layer 122 can then be removed by etching selectively with respect to the second etch barrier 326. With the second etch barrier 326, a relatively thick bond layer can be provided which can be patterned by selective etching, with the second etch barrier 326 protecting underlying structure. Finally, after the exposed portions of the bond layer are removed, portions of the second etch barrier 326 which are exposed between the posts can be removed.

Alternatively, the second barrier layer 326 can function primarily as a diffusion barrier layer to avoid significant diffusion of the bond layer into the material of the conductive pads 112. FIG. 10 illustrates an interconnection element 350 completed by a method according to this variation (FIG. 9) of the embodiment.

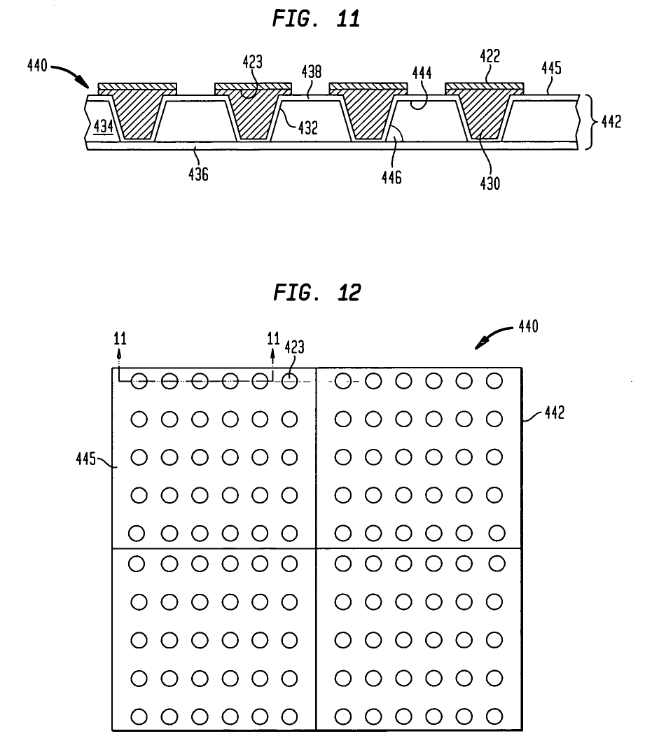

FIG. 11 is a fragmentary sectional view illustrating an alternative layered metal structure 440 for use in fabricating an interconnection element in accordance with a variation of the embodiment described above (FIGS. 1-6). The layered metal structure 440 includes a plurality of conductive posts 430 which are pre-formed within holes or openings 432 of a mandrel 442. FIG. 12 is a plan view of the layered metal structure 440 corresponding to FIG. 11, showing bases 423 of the conductive posts adjacent to a surface 445 of the mandrel 442.

The mandrel can be fabricated according to methods such as described in commonly owned U.S. application Ser. No. 12/228,890 filed Aug. 15, 2008 entitled “Interconnection Element with Posts Formed by Plating” which names Jinsu Kwon, Sean Moran and Endo Kimitaka as inventors, U.S. application Ser. No. 12/228,896 filed Aug. 15, 2008 entitled “Interconnection Element with Plated Posts Formed on Mandrel” which names Sean Moran, Jinsu Kwon and Endo Kimitaka as inventors and U.S. Provisional Application Nos. 60/964,823 (filed Aug. 15, 2007) and 61/004,308 (filed Nov. 26, 2007) the disclosures of which are hereby incorporated by reference herein.

For example, the mandrel 442 can be formed by etching, laser-drilling or mechanically drilling holes in a continuous foil 434 of copper having a thickness of a few tens of microns to over a hundred microns, after which a relatively thin layer 436 of metal (e.g., a copper layer having a thickness from a few microns to a few tens of microns) is joined to the foil to cover the open ends of the holes. The characteristics of the hole-forming operation can be tailored so as to achieve a desired wall angle 446 between the wall of the hole 432 and the surface of the metal layer 436. In particular embodiments, the wall angle can be acute or can be a right angle, depending upon the shape of the conductive posts to be formed.

As covered by the metal layer 436, the holes are then blind openings. An etch barrier layer 438 then is formed extending along bottoms and walls of the openings and overlying an exposed major surface 444 of the foil. In one example, a layer of nickel can be deposited onto a copper foil as the etch barrier layer 438. Thereafter, a layer of metal is plated onto the etch barrier layer to form posts 430. A series of patterning and deposition steps results in formation of the conductive posts with portions 422 of a bond layer overlying a base 423 of each post 430.

As illustrated in FIG. 13, the layered metal structure 440 now is juxtaposed with a partially fabricated interconnection element 110 as described above (FIG. 1), with the bases 423 of the conductive posts 430 adjacent to the conductive pads 112. FIG. 14 illustrates the assembly after the posts are joined with the conductive pads through the bond layer portions 422.

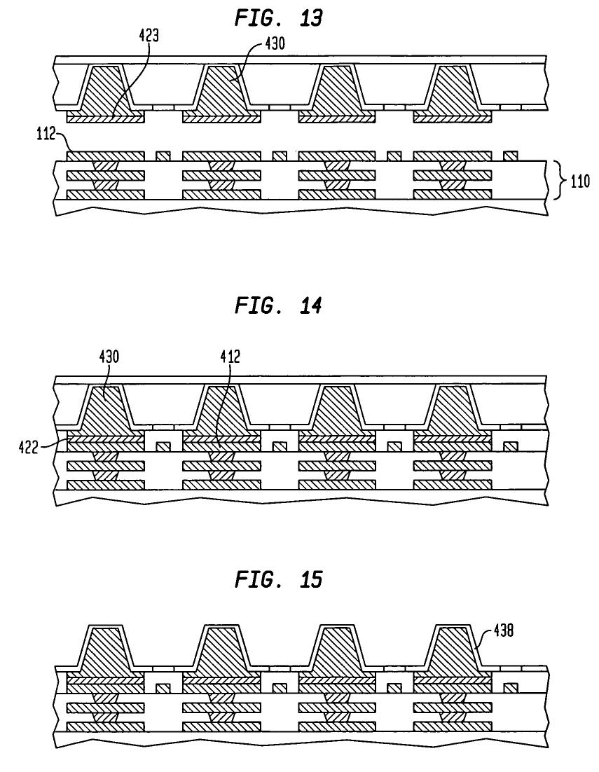

Subsequently, the metal foil 434 and layer 436 of the mandrel are removed as illustrated in FIG. 15, such as by etching a metal of these layers selectively with respect to the etch barrier 438. For example, when the foil 434 and layer 436 consist essentially of copper, they can be etched selectively with respect to an etch barrier 438 consisting essentially of nickel.

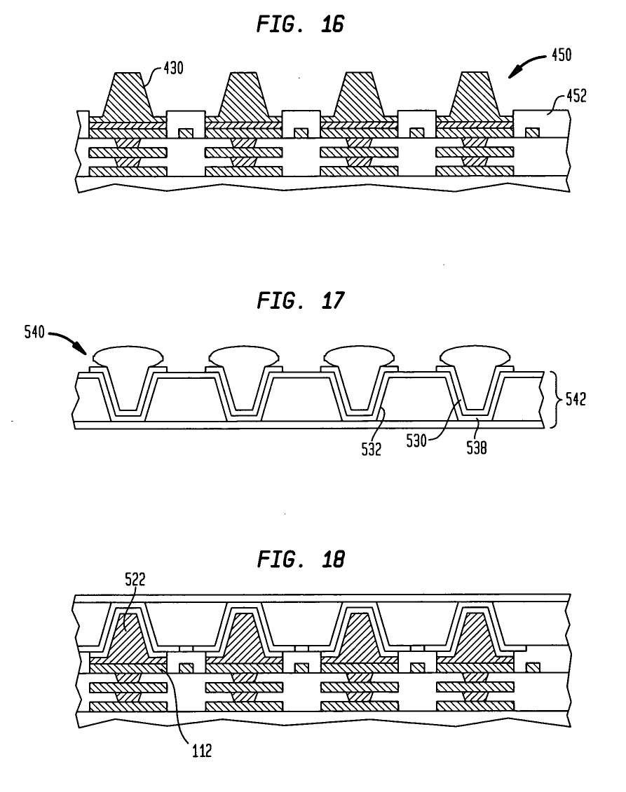

Thereafter, the etch barrier can be removed, and a solder mask 452 applied, resulting in the interconnection element 450 as illustrated in FIG. 16. Subsequent processing can then proceed as described above (FIGS. 1-6) to form a finish metal layer or other joining metal on the posts 430.

In a variation of such embodiment (FIGS. 11-16), a layered metal structure 540 (FIG. 17) can be prepared in which conductive posts 530 of a higher melting temperature metal such as copper are electroplated onto walls of the openings 532. In this variation, the posts are formed as hollow elements overlying an etch barrier 538 within the openings 532 of the mandrel 542. A bond material 522, e.g., a joining metal such as tin, indium, a combination of tin and indium, or other material can then be disposed within the hollow posts as shown. Typically, the bond material has a lower melting temperature than the melting temperature of the hollow conductive posts 530.

Then, as illustrated in FIG. 18, the bond material 522 within the posts is joined under appropriate conditions with the conductive pads 112. Portions of the mandrel can then be removed by etching selectively with respect to the etch barrier 538, in a manner such as described above (FIGS. 15-16). Processing can then proceed as described above to form a solder mask and finish metal layer.

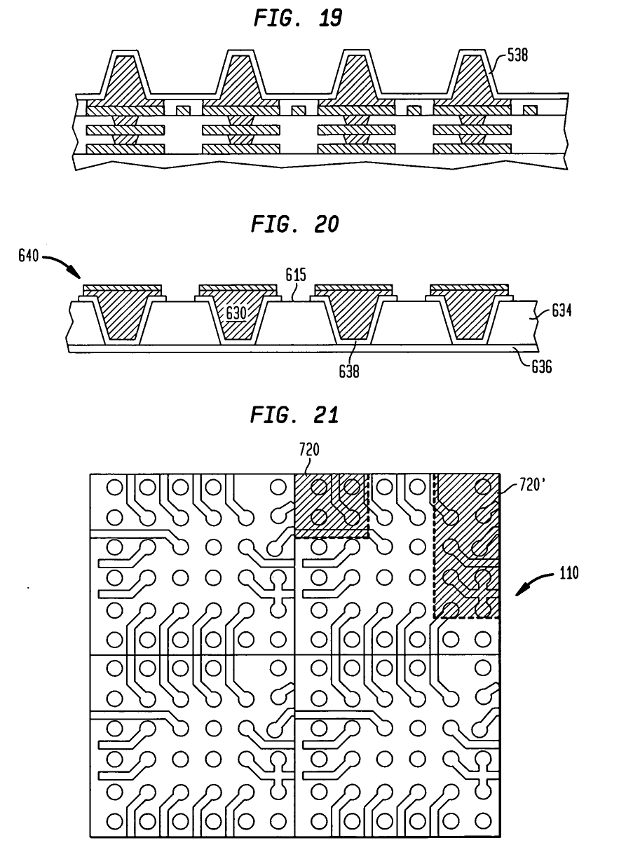

FIG. 20 is a fragmentary sectional view illustrating a layered metal structure 640 utilized in a method of fabrication in accordance with a variation of the above-described embodiments (FIGS. 11-19). In this variation, the mandrel includes a dielectric layer 634 instead of a metal foil, e.g., copper foil, as described above. Metal layer 636 is used as an electrical communing layer when electroplating a metal layer such as copper to form the posts 630 within the openings of the mandrel. In this way, after removing the metal layer 636, the dielectric layer 634 can be removed selectively using a process which can be tailored so as not to affect structure such as traces 116 (FIG. 1) which may be exposed at a surface of the partially fabricated interconnection element. In this way, the etch barrier 638 can be relatively thin and need not cover the entire major surface 615 of the dielectric layer 634.

In yet another variation, shown in plan view in FIG. 21, it is noted that it is not necessary for any or all of the above-described methods (FIGS. 1-20) to be practiced with respect to an entirety of a substrate panel, e.g., a square panel having dimensions of 500 millimeters by 500 millimeters. Instead, it is also contemplated that a plurality of separate layered metal structures 720, 720′ each being smaller than the substrate panel 110 can be joined thereto and processed as described above. For example, a pick-and-place tool can be used to place a layered metal structure as described in the foregoing onto some exposed conductive pads on the substrate panel in particular locations as required. The layered metal structures can then be bonded to the conductive pads in accordance with one or more of the above-described processes. Conductive pads and traces which remain uncovered by any such layered metal structure can be protected from subsequent processing by deposition of an appropriate removable protective layer, e.g., a removable polymer layer. Processing can then proceed in accordance with one or more of the above-described methods.

Some or all of the above-described methods can be applied to form a component in which posts which extend from contacts, e.g., bond pads of a microelectronic element which includes a semiconductor chip. Thus, the resulting product of the above-described methods can be a semiconductor chip having at least one of active or passive devices thereon and having posts which extend away from conductive elements, e.g., pads, exposed at a surface of the chip. In a subsequent process, the posts extending away from the chip surface can be joined with contacts of a component such as a substrate, interposer, circuit panel, etc., to form a microelectronic assembly. In one embodiment, such microelectronic assembly can be a packaged semiconductor chip or can include a plurality of semiconductor chips packaged together in a unit with or without electrical interconnections between the chips.

The methods disclosed herein for forming posts joined with conductive elements of a substrate can be applied to a microelectronic substrate, such as a single semiconductor chip or can be applied simultaneously to a plurality of individual semiconductor chips which can be held at defined spacings in a fixture or on a carrier for simultaneous processing. Alternatively, the methods disclosed herein can be applied to a microelectronic substrate or element including a plurality of semiconductor chips which are attached together in form of a wafer or portion of a wafer to perform processing as described above simultaneously with respect to a plurality of semiconductor chips on a wafer-level, panel-level or strip-level scale.

While the above description makes reference to illustrative embodiments for particular applications, it should be understood that the claimed invention is not limited thereto. Those having ordinary skill in the art and access to the teachings provided herein will recognize additional modifications, applications, and embodiments within the scope of the appended claims.

What is claimed is:

1. An interconnection element comprising:
a substrate having a surface and a plurality of metal conductive elements exposed at the surface;
a plurality of solid metal posts overlying and projecting away from respective ones of the conductive elements; and
an intermetallic layer disposed between the posts and the conductive elements and providing electrically conductive interconnection between the posts and the conductive elements.

2. An interconnection element as claimed in claim 1, wherein the posts have bases adjacent to the intermetallic layer, wherein the bases of the posts are aligned with the intermetallic layer.

3. An interconnection element as claimed in claim 1, wherein the intermetallic layer has a higher melting temperature than a melting temperature of an originally provided bond layer used to form the intermetallic layer.

4. An interconnection element as claimed in claim 1, wherein the intermetallic layer includes at least one metal selected from a tin metal group consisting of tin, tin-copper, tin-lead, tin-zinc, tin-bismuth, tin-indium, tin-silver-copper, tin-zinc-bismuth, and tin-silver-indium-bismuth.

5. An interconnection element as claimed in claim 1, wherein at least one post has a base, a tip remote from the base at a height from the base, and a waist between the base and the tip, the tip having a first diameter, and the waist having a second diameter, wherein a difference between the first and second diameters is greater than 25% of the height of the post.

6. An interconnection element as claimed in claim 1, wherein the posts extend in a vertical direction above the intermetallic layer and have edges which are curved continuously with respect to the vertical direction from tips of the posts to bases of the posts.

7. An interconnection element as claimed in claim 1, wherein the posts extend in a vertical direction above the intermetallic layer and at least one post includes a first etched portion having a first edge, the first edge having a first radius of curvature, and at least one second etched portion between the first etched portion and the intermetallic layer, the second etched portion having a second edge having a second radius of curvature different from the first radius of curvature.

8. An interconnection element as claimed in claim 1, wherein the substrate includes a dielectric element and the conductive elements are exposed at a surface of the dielectric element.

9. An interconnection element as claimed in claim 1, wherein the substrate includes a microelectronic element including a semiconductor chip and the conductive elements are exposed at a surface of the microelectronic element.

10. A method of fabricating a microelectronic interconnection element, comprising:
(a) joining a sheet-like conductive element to exposed conductive elements of a substrate having at least one wiring layer thereon; and
(b) subtractively patterning the sheet-like element to form a plurality of conductive posts projecting in a first direction from the conductive elements, wherein the sheet-like element is joined with the conductive elements of the dielectric element through a conductive bond layer, the step of subtractively patterning the sheet-like element including (i) etching the sheet-like element selectively with respect to the bond layer until portions of the bond layer are exposed and (ii) removing the exposed portions of the bond layer.

11. A method as claimed in claim 10, wherein the bond layer includes at least one of tin or indium.

12. A method as claimed in claim 10, wherein the sheet-like element includes a foil including a first metal, an etch barrier layer overlying a surface of the foil and the conductive bond layer overlying a surface of the etch barrier layer remote from the first metal, step (a) includes joining the bond layer to the conductive elements, and step (b) further comprises etching the foil selectively with respect to the etch barrier layer until portions of the etch barrier layer are exposed, removing exposed portions of the etch barrier layer and removing portions of the bond layer between the conductive posts.

13. A method as claimed in claim 10, wherein the sheet-like element includes a foil including a first metal and a conductive bond layer overlying a surface of the foil, and step (a) includes joining the bond layer with the conductive elements, step (b) further comprises etching the foil selectively with respect to the bond layer until portions of the bond layer are exposed, and removing the exposed portions of the bond layer.

14. A method as claimed in claim 13, wherein the bond layer is a first bond layer, the method further comprising joining the first bond layer with a second bond layer on the conductive elements.

15. A method as claimed in claim 14, wherein the materials of the first and second bond layers are different.

16. A method as claimed in claim 15, wherein one of the first and second bond layers includes tin and gold and the other of the first and second bond layers includes silver and indium.

17. A method as claimed in claim 12, wherein step (b) is performed using an etchant, the foil consists essentially of a first metal and the etch barrier layer consists essentially of an etch barrier layer which is not attacked by the etchant.

18. A method as claimed in claim 17, wherein the first metal includes copper and the etch barrier layer consists essentially of nickel.

19. A method as claimed in claim 12, wherein the etch barrier layer is a first etch barrier layer and the sheet-like conductive element includes a second etch barrier layer overlying a surface of the bond layer remote from the first etch barrier layer.

20. A method as claimed in claim 10, wherein the dielectric element includes has a major surface at which the conductive pads are exposed and a plurality of conductive vias connecting the pads with the traces, the traces being separated from the major surface of the dielectric layer by at least a portion of the thickness of the dielectric element.

21. A method as claimed in claim 10, wherein the substrate includes a microelectronic element including a semiconductor chip and the conductive elements include pads at a face of the semiconductor chip.

22. A method of fabricating a microelectronic interconnection element, comprising:
(a) joining a sheet-like conductive element to exposed conductive pads of an dielectric element having at least one wiring layer thereon; and
(b) subtractively patterning the sheet-like conductive element to form a plurality of conductive posts projecting in a first direction from the conductive pads, wherein the sheet-like conductive element includes a foil including a first metal and a second metal layer overlying a surface of the foil,
wherein step (a) includes joining the second metal layer to the conductive pads with a bond material and step (b) includes etching the foil selectively with respect to the second metal layer until portions of the second metal layer are exposed, and subsequently removing the exposed portions of the second metal layer.

23. A method of fabricating a microelectronic interconnection element, comprising:
(a) juxtaposing first ends of metal posts which are at least partially disposed within openings in a mandrel with conductive elements of a substrate and a conductive bond layer disposed between the first ends of the posts and the conductive elements;
(b) heating at least the bond layer to form electrically conductive joints between the first ends of the posts and the conductive elements; and
(c) removing the mandrel to expose the posts such that posts project away from the conductive elements.

24. A method as claimed in claim 23, wherein the posts have second ends remote from the first ends, wherein a width of the second end of at least one of the posts is smaller than a width of the first end of the at least one post.

25. A method as claimed in claim 23, further comprising, prior to step (a), forming the plurality of conductive posts within the openings of the mandrel by processing including plating a layer of metal within the openings.

26. A method as claimed in claim 25, wherein the mandrel includes a first metal layer exposed at interior walls of the openings, and the conductive posts include a second metal layer overlying the first metal layer within the openings, with an etch barrier layer disposed between the first and second metal layers, wherein the step of removing the mandrel includes removing the first metal layer selectively with respect to the etch barrier metal layer.

27. A method as claimed in claim 26, wherein each of the first metal layer and the second metal layer consists essentially of copper.

28. A method as claimed in claim 27, wherein the etch barrier metal layer consists essentially of nickel.

29. A method as claimed in claim 25, wherein the mandrel includes a dielectric layer exposed at walls of the openings and, in step (b), the mandrel is removed by etching the dielectric layer of the mandrel selectively with respect to a metal included in the conductive posts.

30. A method as claimed in claim 23, wherein the substrate includes a microelectronic element including a semiconductor chip and the conductive elements include pads at a face of the semiconductor chip.

31. A microelectronic interconnection element comprising:
a substrate having a major surface extending in a first direction and a second direction transverse to the first direction;
a plurality of conductive elements exposed at the major surface;
a plurality of solid metal posts overlying and projecting in a third direction away from respective ones of the conductive elements, each post having at least one edge bounding the post in the first direction; and
a conductive bond layer having a first face joined to the respective ones of the conductive elements, the bond layer having at least one edge bounding the bond layer in the first direction,
wherein the edges of the posts and the bond layer are aligned in the first direction.

32. A microelectronic interconnection element as claimed in claim 31, wherein the conductive elements are recessed below a major surface of a dielectric layer overlying the major surface of the substrate.

33. A microelectronic interconnection element as claimed in claim 31, wherein at least one edge of one of conductive posts extends beyond the aligned edges of the post and the bond layer joined to the conductive post.

34. A microelectronic interconnection element as claimed in claim 31, wherein the edges of at least one of the posts and the bond layer aligned therewith extend beyond at least one edge of one of the conductive pads to which the post is joined.

35. A microelectronic interconnection element as claimed in claim 31, wherein the substrate includes a dielectric element, the interconnection element further comprising a plurality of traces embedded within the dielectric element and extending in at least one of the first or second directions.

36. A microelectronic interconnection element as claimed in claim 31, wherein the substrate includes a microelectronic element including a semiconductor chip and the conductive elements include pads at a face of the semiconductor chip.

37. A method of fabricating an interconnection element comprising:
juxtaposing a metal foil extending in first and second directions with a plurality of electrically conductive elements of a substrate and an electrically conductive bond layer disposed between a face of the metal foil and the conductive elements;
applying heat to join the metal foil with the conductive elements and form an intermetallic layer at least at junctions between the metal foil and the conductive elements; and
patterning the metal foil to form a plurality of solid metal posts extending away from the conductive elements and away from a surface of the substrate.

38. The method of fabricating an interconnection element as claimed in claim 37, wherein the intermetallic layer has a melting temperature higher than a temperature at which a joining process usable to form electrically conductive interconnections between the posts and contacts of an external component.

39. A method as claimed in claim 37, wherein the substrate includes a microelectronic element including a semiconductor chip and the conductive elements include pads at a face of the semiconductor chip.
